(19) United States
(12) Patent Application Publication
(10) Pub. No.: US 2014/0159144 A1
(43) Pub. Date: Jun. 12, 2014

(54) TRENCH GATE MOSFET AND METHOD OF FORMING THE SAME

(71) Applicant: Beyond Innovation Technology Co., Ltd., Taipei City (TW)

(72) Inventor: Chien-Hsing Cheng, Taipei City (TW)

(73) Assignee: Beyond Innovation Technology Co., Ltd., Taipei City (TW)

(21) Appl. No.: 14/028,522

(22) Filed: Sep. 16, 2013

(30) Foreign Application Priority Data
Dec. 12, 2012 (TW) 101146957

(51) Int. Cl. H01L 29/66; H01L 29/78

(52) U.S. Cl. CPC H01L 29/66666; H01L 29/7827
USPC 257/330; 438/270

(57) ABSTRACT

A trench gate MOSFET is provided. An N-type epitaxial layer on an N-type substrate has a wider first trench and a narrower second trench below the first trench. A first insulating layer is in the second trench. First and second conductive layers are respectively in lower and upper portions of the first trench. A thicker second insulating layer is between the first conductive layer and N-type epitaxial layer and between the first insulating layer and first conductive layer, and a thinner third insulating layer is between the second conductive layer and N-type epitaxial layer. A P-type first doped region is in the N-type epitaxial layer below the first trench and surrounds the top of the second trench. A P-type second doped region is in the N-type epitaxial layer below the second trench. A source region is in the N-type epitaxial layer and surrounds the top of the first trench.

### CROSS-REFERENCE TO RELATED APPLICATION

This application claims the priority benefits of Taiwan application serial no. 101146957, filed on Dec. 12, 2012. The entirety of the above-mentioned patent applications is hereby incorporated by reference herein and made a part of this specification.

### BACKGROUND OF THE INVENTION

1. Field of the Invention

The invention relates to a semiconductor device, and more particularly, to a trench gate MOSFET and a method of forming the same.

2. Description of Related Art

Trench gate MOSFET has been widely applied in power switch devices, such as power supplies, rectifiers, low-voltage motor controllers, or so forth. In general, the trench gate MOSFET is often resorted to a design of vertical structure to enhance the device density. For each power MOSFET, each drain region is formed on the back-side of a chip, and each source region and each gate are formed on the front-side of the chip. The drain regions of the transistors are connected in parallel so as to endure a considerable large current.

The channel “on” resistance (Ron) and the breakdown voltage (BV) of the trench gate MOSFET usually maintain a power relationship of 2.4-2.5, that is, Ron∝(BV)^{2.4-2.5}. In other words, as the rated voltage is higher, the chip size is greater, and therefore the Ron is also increased. Accordingly, achieving higher withstand voltage and lower Ron while maintaining the same or smaller chip size has become the greatest challenge in the design of the trench gate MOSFET.

### SUMMARY OF THE INVENTION

The invention provides a trench gate MOSFET and a method of forming the same. The method can form a trench gate MOSFET having higher withstand voltage and lower Ron while maintaining the same or smaller chip size.

The invention provides a trench gate MOSFET including a substrate of a first conductivity type, an epitaxial layer of the first conductivity type, a first insulating layer, a first conductive layer, a second conductive layer, a second insulating layer, a third insulating layer, a first doped region of a second conductivity type, a second doped region of the second conductivity type, and a source region of the first conductivity type. The epitaxial layer is disposed on the substrate, wherein the epitaxial layer has a first trench and a second trench below the first trench, and the width of the first trench is greater than the width of the second trench. The first insulating layer is disposed in the second trench. The first conductive layer is disposed in the lower portion of the first trench. The second conductive layer is disposed in the upper portion of the first trench. The second insulating layer is disposed between the first conductive layer and the epitaxial layer and between the first insulating layer and the first conductive layer. The third insulating layer is disposed between the second conductive layer and the epitaxial layer, and the thickness of the second insulating layer is greater than the thickness of the third insulating layer. The first doped region is disposed in the epitaxial layer below the first trench and surrounds the top of the second trench. The second doped region is disposed in the epitaxial layer below the second trench. The source region is disposed in the epitaxial layer and surrounds the top of the first trench.

In an embodiment of the invention, the trench gate MOSFET further includes at least one third doped region of the second conductivity type disposed in the epitaxial layer between the first doped region and the second doped region and surrounding the sidewall of the second trench.

In an embodiment of the invention, the first doped region, the second doped region, and the third doped region are separated from one another.

In an embodiment of the invention, each of the first conductive layer and the second conductive layer includes doped polysilicon.

In an embodiment of the invention, the trench gate MOSFET further includes a fourth doped region of the second conductivity type and a fifth doped region of the first conductivity type. The fourth doped region is disposed in the epitaxial layer below the source region. The fifth doped region is disposed in the epitaxial layer below the fourth doped region.

In an embodiment of the invention, the trench gate MOSFET further includes a dielectric layer and a third conductive layer. The dielectric layer is disposed on the second conductive layer and the source region. The third conductive layer is disposed on the dielectric layer and electrically connected to the source region.

In an embodiment of the invention, the third conductive layer includes metal.

In an embodiment of the invention, the third conductive layer is electrically connected to the source region through at least one conductive plug, and the conductive plug passes through the dielectric layer and the source region and extends to a portion of the fourth doped region.

In an embodiment of the invention, the trench gate MOSFET further includes a sixth doped region of the second conductivity type disposed in the fourth doped region below the conductive plug.

In an embodiment of the invention, the first conductivity type is N-type and the second conductivity type is P-type, or the first conductivity type is P-type and the second conductivity type is N-type.

The invention further provides a method of forming a trench gate MOSFET. An epitaxial layer of a first conductivity type is formed on a substrate of the first conductivity type. A source region of the first conductivity type is formed in the epitaxial layer. A first trench is formed in the epitaxial layer. A first doped region of a second conductivity type is formed in the epitaxial layer below the first trench. A spacer is formed on the sidewall of the first trench. A portion of the substrate is removed by using the spacer as a mask to form a second trench in the epitaxial layer below the first trench. A second doped region of the second conductivity type is formed in the epitaxial layer below the second trench. The spacer is then removed. A first insulating layer completely fills the second trench. A second insulating layer is formed on the sidewall of the first trench and on the top surface of the first insulating layer. A first conductive layer is filled in the lower portion of the first trench. The second insulating layer not covered by the first conductive layer is thinned to form a third insulating layer. A second conductive layer is filled in the upper portion of the first trench.

In an embodiment of the invention, the method further includes, after forming the second doped region and before removing the spacer, removing another portion of the substrate by using the spacer as a mask to deepen the second trench, and forming a third doped region of the second conductivity type below the deepened second trench.

In an embodiment of the invention, each of the first conductive layer and the second conductive layer includes doped polysilicon.

In an embodiment of the invention, the method of forming the source region includes performing a blanket implant process.

In an embodiment of the invention, the method of forming the spacer on the sidewall of the first trench includes conformally forming a spacer material layer on the surfaces of the epitaxial layer and the first trench, and performing an anisotropic etching process to remove a portion of the spacer material layer.

In an embodiment of the invention, the spacer material layer includes silicon nitride.

In an embodiment of the invention, the method of thinning the second insulating layer not covered by the first conductive layer includes performing a plasma etching process.

In an embodiment of the invention, the method further includes, before forming the first trench, forming a fourth doped region of the second conductivity type in the epitaxial layer below the source region, and forming a fifth doped region of the first conductivity type in the epitaxial layer below the fourth doped region.

In an embodiment of the invention, the method of forming the source region, the fourth doped region, and the fifth doped region includes performing a first blanket implant process to form a bulk doped region of the first conductivity type in the epitaxial layer, and performing a second blanket implant process to form the fourth doped region in the bulk doped region, wherein the remaining bulk doped region above the fourth doped region is used as the source region and the remaining bulk doped region below the fourth region is used as the fifth doped region.

In an embodiment of the invention, the method further includes, after forming the second conductive layer, forming a dielectric layer on the second conductive layer and the source region, and forming a third conductive layer on the dielectric layer, wherein the third conductive layer and the source region are electrically connected.

In an embodiment of the invention, the third conductive layer includes metal.

In an embodiment of the invention, the third conductive layer is electrically connected to the source region through at least one conductive plug.

In an embodiment of the invention, the method of forming the conductive plug includes forming at least one opening in the dielectric layer, wherein the opening passes through the source region and extends to a portion of the fourth doped region, and forming the third conductive layer on the dielectric layer, wherein the third dielectric layer is filled in the opening.

In an embodiment of the invention, the method further includes, after forming the opening and before forming the third conductive layer, forming a sixth doped region of the second conductivity type in the fourth doped region below the opening.

In an embodiment of the invention, the first conductivity type is N-type and the second conductivity type is P-type, or the first conductivity type is P-type and the second conductivity type is N-type.

Based on the above, in the trench gate MOSFET of the invention, by designing a RESURF stepped oxide layer (formed by the second insulating layer and the third insulating layer) and a super junction (formed by the first to third doped regions and the epitaxial layer), the withstand voltage of the product is increased, the area of the product is reduced and the characteristics of the product is optimized. Moreover, the method of the invention is relatively simple in that no additional photomasks are needed. The structure of the RESURF stepped oxide layer can be completed by using a pull back plasma etching process, and the super junction structure can be completed by using at least one self-aligned process, thereby significantly lowering cost and improving competitiveness.

In order to make the aforementioned features and advantages of the invention more comprehensible, embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1A to 1I are schematic cross-sectional views of a method of forming a trench gate MOSFET according to an embodiment of the invention.

### DESCRIPTION OF THE EMBODIMENTS

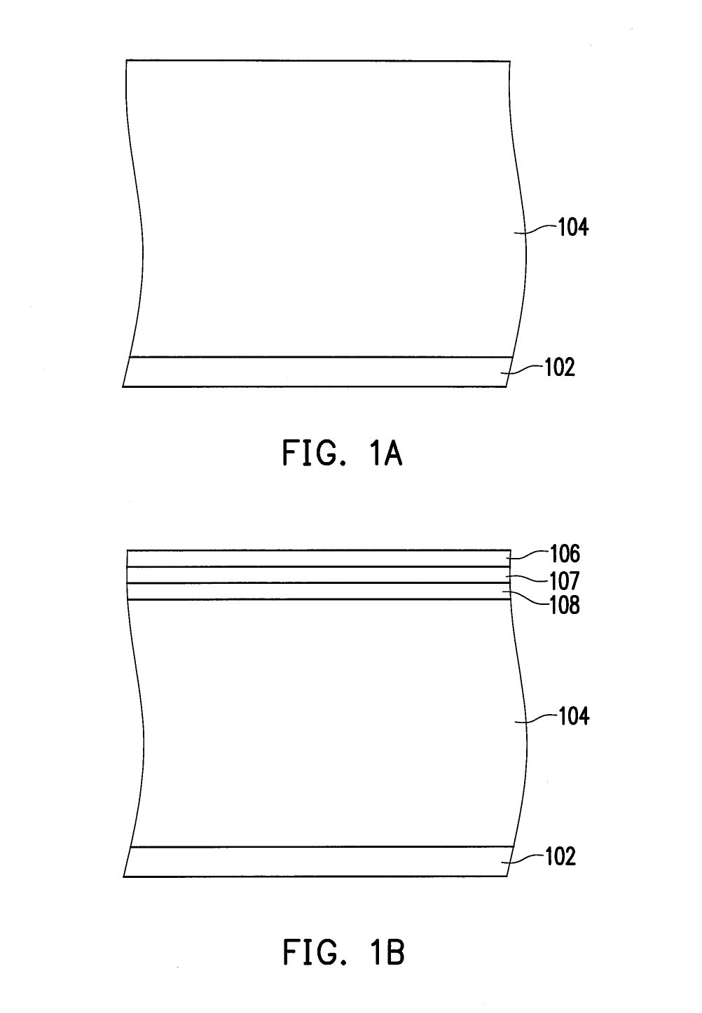

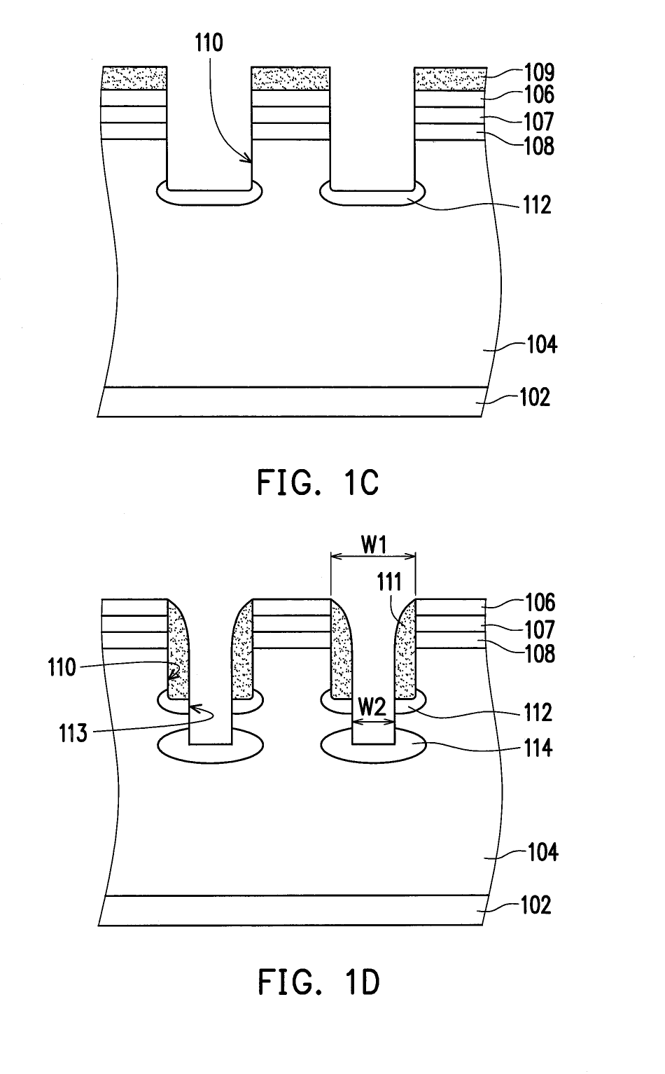

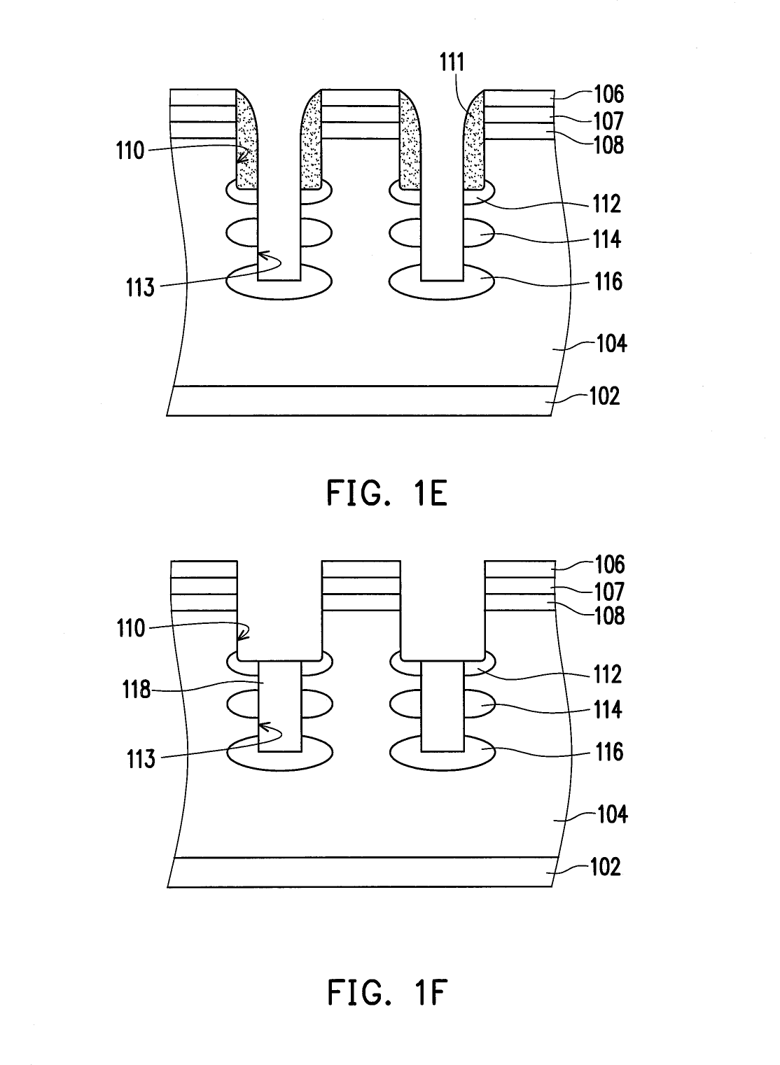

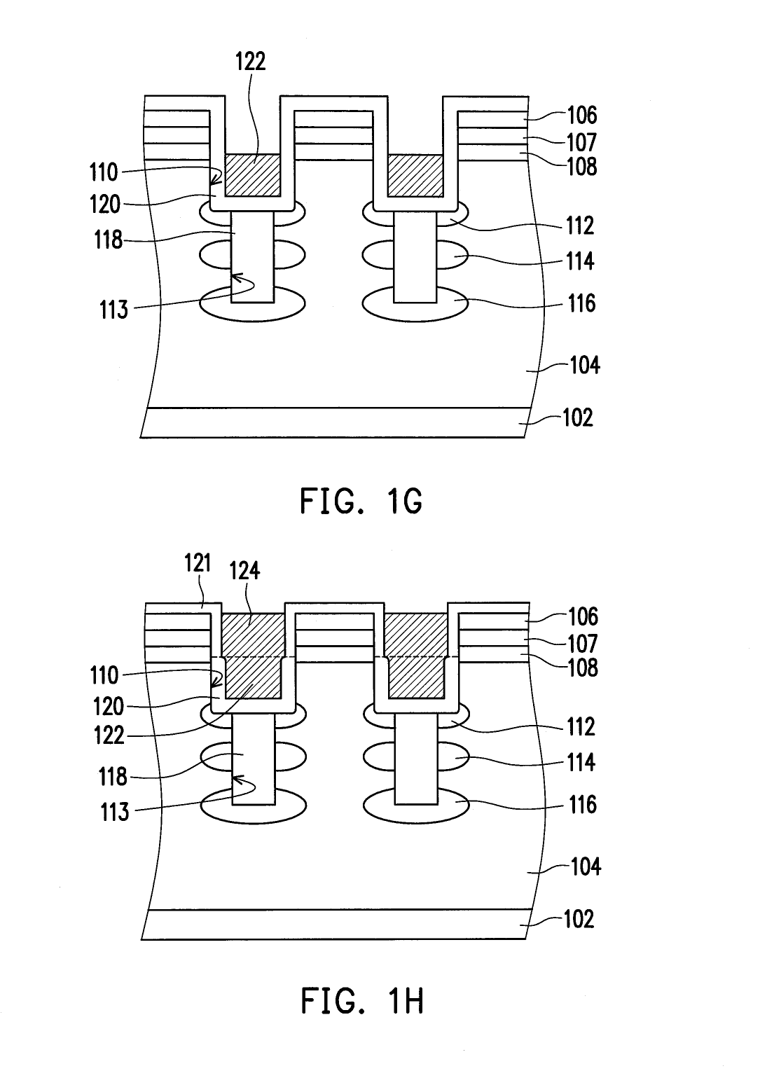

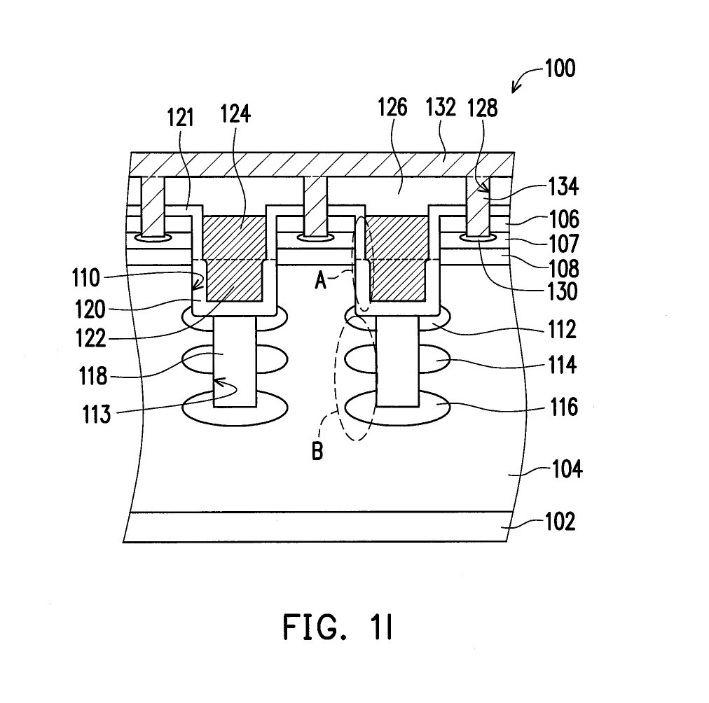

FIGS. 1A to 1I are schematic cross-sectional views of a method of forming a trench gate MOSFET according to an embodiment of the invention.

First, referring to FIG. 1A, an epitaxial layer 104 of a first conductivity type is formed on a substrate 102 of the first conductivity type. The substrate 102 is, for instance, an N-type heavily doped (N⁺) silicon substrate that can be used as the drain of a trench gate MOSFET. The epitaxial layer 104 is, for instance, an N-type lightly doped (N⁻) epitaxial layer, and a forming method thereof includes performing a selective epitaxy growth (SEG) process.

Referring to FIG. 1B, a source region 106 of the first conductivity type, a doped region 107 of a second conductivity type, and a doped region 108 of the first conductivity type (from top to bottom counting from the surface of the epitaxial layer 104) are formed in the epitaxial layer 104. The source region 106 is, for instance, an N⁺ doped region, the doped region 107 is, for instance, a P⁻ doped region, and the doped region 108 is, for instance, an N⁺ doped region. The doped region 107 can define a P-type body well and the doped region 108 can provide a lower resistance path to reduce Rds(ON) of the device.

In an embodiment, a first blanket implant process can be performed with an N-type dopant to form a bulk N⁺ doped region (not shown) in the epitaxial layer 104. The N-type dopant includes phosphorous or arsenic. Then, a second blanket implant process is performed with a P-type dopant to form a P⁻ doped region used as the doped region 107 in the bulk N⁺ doped region. The P-type dopant includes boron. Here, the remaining bulk N⁺ doped region above the P⁻ doped region can be used as the source region 106 and the remaining bulk N⁺ doped region below the P⁻ doped region can be used as the doped region 108.

In another embodiment, the method of forming each of the source region 106, the doped region 107, and the doped region 108 includes performing a blanket implant process, and the invention does not limit the order of formation thereof.

It should be mentioned that, the step of forming the doped region 108 is an optional step and can be omitted according to process needs. In other words, two blanket implant processes can be performed to form only the source region 106 and the doped region 108 in the epitaxial layer 104.

Referring to FIG. 1C, a trench 110 is formed in the epitaxial layer 104. The trench 110 passes through the source region 106, the doped region 107 and the doped region 108 and extends to a portion of the epitaxial layer 104. The method of forming the trench 110 includes forming a mask layer 109 on the epitaxial layer 104. The mask layer 109 includes silicon nitride, and the forming method thereof includes performing chemical vapor deposition and a subsequent photolithography process. Then, using the mask layer 109 as a mask, an etching process is performed to form the trench 110 in the epitaxial layer 104.

Next, a doped region 112 of the second conductivity type is formed in the epitaxial layer 104 below the trench 110. The doped region 112 is, for instance, a P⁻ doped region. The method of forming the doped region 112 includes performing an ion implantation process by using the mask layer 109 as a mask. Then, a drive-in process is performed such that the doped region 112 is diffused outwardly to cover the bottom and a portion of the lower sidewall of the trench 110. Since the ion implantation process uses the mask layer 109 as a mask, the process can be regarded as a self-aligned process allowing the doped region 112 to be accurately formed below the trench 110. Thereafter, the mask layer 109 is removed.

Referring to FIG. 1D, a spacer 111 is formed on the sidewall of the trench 110. The method of forming the spacer 111 includes conformally forming a spacer material layer (not shown) on the surface of the epitaxial layer 104 and the trench 110. The spacer material layer includes silicon nitride and the forming method thereof includes performing a chemical vapor deposition process. Then, an anisotropic etching process is performed to remove a portion of the spacer material layer.

Next, using the spacer 111 as a mask, a portion of the substrate 102 is removed to form a trench 113 in the epitaxial layer 104 below the trench 110. The method of forming the trench 113 includes performing an etching process. Since the etching process uses the spacer 111 as a mask, the process can be regarded as a self-aligned process, and the width W2 of the trench 113 is less than the width W1 of the trench 110.

Next, a doped region 114 of the second conductivity type is formed in the epitaxial layer 104 below the trench 113. The doped region 114 is, for instance, a P⁻ doped region. The method of forming the doped region 114 includes performing an ion implantation process by using the spacer 111 as a mask. Then, a drive-in process is performed such that the doped region 114 is diffused outwardly to cover the bottom and a portion of the lower sidewall of the trench 113. Since the ion implantation process uses the spacer 111 as a mask, the process can be regarded as a self-aligned process allowing the doped region 114 to be accurately formed below the trench 113.

Referring to FIG. 1E, another portion of the substrate 102 is removed by again using the spacer 111 as a mask to deepen the trench 113. The deepening step includes performing an etching process. In this step, the trench 113 is deepened to pass through the doped region 114 such that the doped region 114 is configured to surround the sidewall of the trench 113. Then, a doped region 116 of the second conductivity type is formed below the deepened trench 113. The doped region 116 is, for instance, a P⁻ doped region. The method of forming the doped region 116 includes performing an ion implantation process and a subsequent drive-in process by using the spacer 111 as a mask such that the doped region 116 is diffused outwardly to cover the bottom and a portion of the lower sidewall of the trench 113. The step of deepening the trench and the step of forming the P⁻ doped region below the deepened trench are also self-aligned processes and can be performed without the need of additional photomasks.

It should be mentioned that, the step of FIG. 1E is an optional step and can be omitted or performed multiple times according to process needs. In the present embodiment, the step of FIG. 1E is performed once, but the invention is not limited thereto. Those having ordinary skill in the art should know that the step of FIG. 1E can be performed multiple times until the trench 113 reaches the desired depth. When the trench 113 reaches the desired depth, the spacer 111 can be removed.

Referring to FIG. 1F, an insulating layer 118 completely fills the trench 113. The method of forming the insulating layer 118 includes forming an insulating material layer (not shown) on the epitaxial layer 104, wherein the insulating material layer is filled in the trenches 110 and 113. The insulating material layer includes silicon oxide and the forming method thereof includes performing a chemical vapor deposition process or a high-density plasma process. Then, an etching back process is performed to remove the insulating material layer in the trench 110 and leave the insulating material layer in the trench 113.

Referring to FIG. 1G, an insulating layer 120 is formed on the sidewall of the trench 113 and on the top surface of the insulating layer 118. In an embodiment, the insulating layer 120 can be further extended onto the surface of the epitaxial layer 104. The insulating layer 120 includes silicon oxide and the forming method thereof includes performing a chemical vapor deposition process.

Then, a conductive layer 122 is filled in the lower portion of the trench 110. The method of forming the conductive layer 122 includes forming a first conductive material layer (not shown) on the epitaxial layer 104, wherein the first conductive material layer is filled in the trench 110. The first conductive material layer includes doped polysilicon and the forming method thereof includes performing a chemical vapor deposition process. Then, an etching back process is performed to remove a portion of the first conductive material layer.

Referring to FIG. 1H, a pull back plasma etching process is performed to thin the insulating layer 120 not covered by the conductive layer 122 and therefore form an insulating layer 121. As a result, the thickness of the insulating layer 121 is less than the thickness of the insulating layer 120.

Then, a conductive layer 124 is filled in the upper portion of the trench 110. The method of forming the conductive layer 124 includes forming a second conductive material layer (not shown) on the epitaxial layer 104, wherein the second conductive material layer is filled in the trench 110. The second conductive material layer includes doped polysilicon and the forming method thereof includes performing a chemical vapor deposition process. Then, an etching back process is performed to remove a portion of the second conductive material layer.

Referring to FIG. 1I, a dielectric layer 126 is formed on the conductive layer 124 and the source region 106. The dielectric layer 126 includes silicon oxide, borophosphosilicate glass (BPSG), phosphosilicate glass (PSG), fluorosilicate glass (FSG), or undoped silicon glass (USG), and the forming method thereof includes performing a chemical vapor deposition process. Then, at least one opening 128 is formed in the dielectric layer 126, and the opening 128 passes through the source region 106 and extends to a portion of the doped region 107. The method of forming the opening 128 includes performing photolithography and etching processes.

Next, a doped region 130 of the second conductivity type is formed in the doped region 107 below the opening 128. The doped region 130 is, for instance, a P⁺ doped region, and the forming method thereof includes performing an ion implantation and a subsequent drive-in process.

Then, a conductive layer 132 is formed on the dielectric layer 126, and the conductive layer 132 is filled in the opening 128 and electrically connected to the source region 106. The conductive layer 132 includes metal such as Ti/TiN/Al, and the forming method thereof includes performing a sputtering process. The conductive layer 132 filled in the opening 128 forms a conductive plug 134. In other words, the conductive layer 132 is electrically connected to the source region 106 through the conductive plug 134. At this point, the fabrication of the trench gate MOSFET 100 is complete, wherein the insulating layers 120 and 121 are used as gate insulating layers and the conductive layers 122 and 124 are used as gates.

In the embodiments, the first conductivity type is N-type and the second conductivity type is P-type. However, the invention is not limited thereto. Those having ordinary skill in the art should know that the first conductivity type can also be P-type and the second conductivity type be N-type.

In the following, the structure of the trench gate MOSFET of the invention is explained though FIG. 1I. As shown in FIG. 1I, the trench gate MOSFET 100 includes an N-type substrate 102, an N-type epitaxial layer 104, an insulating layer 118, a conductive layer 122, a conductive layer 124, an insulating layer 120, an insulating layer 121, a P-type doped region 112, a P-type doped region 114, and an N-type source region 106. The N-type epitaxial layer 104 is disposed on the N-type substrate 102 and the N-type epitaxial layer 104 has a trench 110 and a trench 113 therein, wherein the trench 113 is below the trench 110 and the width of the trench 110 is greater than the width of the trench 113. The insulating layer 118 is disposed in the trench 113. The conductive layer 122 is disposed in the lower portion of the trench 110. The conductive layer 124 is disposed in the upper portion of the trench 110. The insulating layer 120 is disposed between the conductive layer 122 and the N-type epitaxial layer 104 and between the insulating layer 118 and the conductive layer 122. The insulating layer 121 is disposed between the conductive layer 124 and the N-type epitaxial layer 104, and the thickness of the insulating layer 120 is greater than the thickness of the insulating layer 121. The P-type doped region 112 is disposed in the N-type epitaxial layer 104 below the trench 110 and surrounds the top of the trench 113. The P-type doped region 116 is disposed in the N-type epitaxial layer 104 below the trench 113. The N-type source region 106 is disposed in the N-type epitaxial layer 104 and surrounds the top of the trench 110.

It should be mentioned that, in the trench gate MOSFET of the invention, the thicker insulating layer 120 and the thinner insulating layer 121 form a Reduced Surface Field stepped oxide (RESURF stepped oxide, RSO), as shown in the region A of FIG. 1I. The RSO can increase withstand voltage and reduce surface electric field.

Moreover, the trench gate MOSFET 100 can further include at least one P-type doped region 114 disposed in the N-type epitaxial layer 104 between the doped region 112 and the doped region 116, wherein the P-type doped region 114 surrounds the sidewall of the trench 113. The P-type doped region 112, the P-type doped region 114, and the P-type doped region 116 are separate from one another.

It should be mentioned that, in the trench gate MOSFET 100 of the invention, the P-type doped regions 112, 114, and 116 are separately disposed in the N-type epitaxial layer 104 and together form a super junction through the alternately disposed P-type dopant and N-type dopant, as shown in the region B of FIG. 1I. The super junction has the characteristics of high withstand voltage and low impedance.

Moreover, the trench gate MOSFET 100 can further include a P-type doped region 107 and an N-type doped region 108. The P-type doped region 107 is disposed in the N-type epitaxial layer 104 below the N-type source region 106. The N-type doped region 108 is disposed in the N-type epitaxial layer 104 below the P-type doped region 107.

Moreover, the trench gate MOSFET 100 can further include a dielectric layer 126, a conductive layer 132, and a P-type doped region 130. The dielectric layer 126 is disposed on the conductive layer 124 and the source region 106. The conductive layer 132 is disposed on the dielectric layer 126 and electrically connected to the source region 106. The conductive layer 132 is electrically connected to the source region 106 through at least one conductive plug 134 and the conductive plug 134 passes through the dielectric layer 126 and the source region 106 and extends to a portion of the P-type doped region 107. The P-type doped region 130 is disposed in the P-type doped region 107 below the conductive plug 134. The interface between the conductive plug 134 and the P-type doped region 107 can be regarded as an Ohmic contact and the P-type doped region 130 can be used to effectively reduce the resistance of the Ohmic contact.

Based on the above, in the trench gate MOSFET of the invention, by designing the RSO (as shown in the region A of FIG. 1I) and the super junction (as shown in the region B of FIG. 1I), the withstand voltage of the product is effectively increased, the area of the product is reduced and the characteristics of the product is optimized. Specifically, the figure of merit (FOM) can be represented by the product of channel “on” resistance (Rds(ON)) and the gate-drain charge (Qgd), that is, FOM=Rds(ON)×Qgd. The RSO structure of the invention can reduce Rds(ON), but also worsens the dynamic characteristics of the product. For example, the switching loss is increase due to higher input capacitance (Ciss) and Qgd. However, through the design of a thick bottom oxide layer (i.e. insulating layer 118), Qgd can be effectively reduced, thereby reducing the FOM value and improving device performance. Compared to the known MOSFET, in the same unit area, the structure of the invention can achieve lower Ron and switching loss, thereby increasing the power density of each unit area and significantly improving the competitive advantage of the product.

Moreover, the method of the invention is relatively simple in that no additional photomasks are needed. The structure of the RSO can be completed by using a pull back plasma etching process, and the super junction structure can be completed by using at least one self-aligned process, thereby significantly lowering cost and improving competitiveness.

Although the invention has been described with reference to the above embodiments, it will be apparent to one of the ordinary skill in the art that modifications and variations to the described embodiments may be made without departing from the spirit and scope of the invention. Accordingly, the scope of the invention will be defined by the attached claims not by the above detailed descriptions.

What is claimed is:

1. A trench gate MOSFET, comprising:
a substrate of a first conductivity type;
an epitaxial layer of the first conductivity type, disposed on the substrate, wherein the epitaxial layer has a first trench and a second trench below the first trench, and a width of the first trench is greater than a width of the second trench;
a first insulating layer, disposed in the second trench;
a first conductive layer, disposed in a lower portion of the first trench;
a second conductive layer, disposed in an upper portion of the first trench;
a second insulating layer, disposed between the first conductive layer and the epitaxial layer and between the first insulating layer and the first conductive layer;
a third insulating layer, disposed between the second conductive layer and the epitaxial layer, wherein a thickness of the second insulating layer is greater than a thickness of the third insulating layer;
a first doped region of a second conductivity type, disposed in the epitaxial layer below the first trench and surrounding a top of the second trench;
a second doped region of the second conductivity type, disposed in the epitaxial layer below the second trench; and
a source region of the first conductivity type, disposed in the epitaxial layer and surrounding a top of the first trench.

2. The trench gate MOSFET of claim 1, further comprising at least one third doped region of the second conductivity type, disposed in the epitaxial layer between the first doped region and the second doped region and surrounding a sidewall of the second trench.

3. The trench gate MOSFET of claim 2, wherein the first doped region, the second doped region, and the third doped region are separate from one another.

4. The trench gate MOSFET of claim 1, wherein each of the first conductive layer and the second conductive layer comprises doped polysilicon.

5. The trench gate MOSFET of claim 1, further comprising:
a fourth doped region of the second conductivity type, disposed in the epitaxial layer below the source region; and
a fifth doped region of the first conductivity type, disposed in the epitaxial layer below the fourth doped region.

6. The trench gate MOSFET of claim 5, further comprising:
a dielectric layer, disposed on the second conductive layer and the source region; and
a third conductive layer, disposed on the dielectric layer and electrically connected to the source region.

7. The trench gate MOSFET of claim 6, wherein the third conductive layer comprises metal.

8. The trench gate MOSFET of claim 6, wherein the third conductive layer is electrically connected to the source region through at least one conductive plug and the conductive plug passes through the dielectric layer and the source region and extends to a portion of the fourth doped region.

9. The trench gate MOSFET of claim 8, further comprising a sixth doped region of the second conductivity type disposed in the fourth doped region below the conductive plug.

10. The trench gate MOSFET of claim 1, wherein the first conductivity type is N-type and the second conductivity type is P-type, or the first conductivity type is P-type and the second conductivity type is N-type.

11. A method of forming a trench gate MOSFET, comprising:
forming an epitaxial layer of a first conductivity type on a substrate of the first conductivity type;
forming a source region of the first conductivity type in the epitaxial layer;
forming a first trench in the epitaxial layer;
forming a first doped region of a second conductivity type in the epitaxial layer below the first trench;
forming a spacer on a sidewall of the first trench;
removing a portion of the substrate by using the spacer as a mask, so as to form a second trench in the epitaxial layer below the first trench;
forming a second doped region of the second conductivity type in the epitaxial layer below the second trench;
removing the spacer;
completely filling a first insulating layer in the second trench;
forming a second insulating layer on the sidewall of the first trench and on a top surface of the first insulating layer;
filling a first conductive layer in a lower portion of the first trench;
thinning the second insulating layer not covered by the first conductive layer to form a third insulating layer; and
filling a second conductive layer in an upper portion of the first trench.

12. The method of claim 11, further comprising, after forming the second doped region and before removing the spacer:
removing another portion of the substrate by using the spacer as a mask to deepen the second trench; and
forming a third doped region of the second conductivity type below the deepened second trench.

13. The method of claim 11, wherein each of the first conductive layer and the second conductive layer comprises doped polysilicon.

14. The method of claim 11, wherein a method of forming the source region comprises performing a blanket implant process.

15. The method of claim 11, wherein a method of forming the spacer on the sidewall of the first trench comprises:
conformally forming a spacer material layer on surfaces of the epitaxial layer and the first trench; and
performing an anisotropic etching process to remove a portion of the spacer material layer.

16. The method of claim 15, wherein the spacer material layer comprises silicon nitride.

17. The method of claim 11, wherein a method of thinning the second insulating layer not covered by the first conductive layer comprises performing a plasma etching process.

18. The method of claim 11, further comprising, before forming the first trench:
forming a fourth doped region of the second conductivity type in the epitaxial layer below the source region; and
forming a fifth doped region of the first conductivity type in the epitaxial layer below the fourth doped region.

19. The method of claim 18, wherein a method of forming the source region, the fourth doped region, and the fifth doped region comprises:
performing a first blanket implant process to form a bulk doped region of the first conductivity type in the epitaxial layer; and
performing a second blanket implant process to form the fourth doped region in the bulk doped region, wherein a remaining bulk doped region above the fourth doped region is used as the source region and a remaining bulk doped region below the fourth doped region is used as the fifth doped region.

20. The method of claim 18, further comprising, after forming the second conductive layer:
forming a dielectric layer on the second conductive layer and the source region; and
forming a third conductive layer on the dielectric layer, wherein the third conductive layer is electrically connected to the source region.

21. The method of claim 20, wherein the third conductive layer comprises metal.

22. The method of claim 20, wherein the third conductive layer is electrically connected to the source region through at least one conductive plug.

23. The method of claim 22, wherein a method of forming the conductive plug comprises:
forming at least one opening in the dielectric layer, wherein the opening passes through the source region and extends to a portion of the fourth doped region; and
forming the third conductive layer on the dielectric layer, wherein the third conductive layer is filled in the opening.

24. The method of claim 23, further comprising, after forming the opening and before forming the third conductive layer, forming a sixth doped region of the second conductivity type in the fourth doped region below the opening.

25. The method of claim 11, wherein the first conductivity type is N-type and the second conductivity type is P-type, or the first conductivity type is P-type and the second conductivity type is N-type.
